(19) United States
(12) Patent Application Publication
(10) Pub. No.: US 2019/0081420 A1
(43) Pub. Date: Mar. 14, 2019

(54) STACKED INSERTION STRUCTURE FOR FLEXIBLE CIRCUIT BOARD

(71) Applicant: ADVANCED FLEXIBLE CIRCUITS CO., LTD., ZHONGLI CITY (TW)

(72) Inventors: CHIH-HENG CHUO, BADE CITY (TW); KUO-FU SU, ZHONGLI CITY (TW); GWUN-JIN LIN, TAOYUAN CITY (TW)

(21) Appl. No.: 16/002,186

(22) Filed: Jun. 7, 2018

(30) Foreign Application Priority Data
Sep. 8, 2017 (TW) 106130950

(51) Int. Cl. H01R 12/59; H05K 1/11; H05K 1/02

(52) U.S. Cl. CPC H01R 12/59; H05K 1/118; H05K 2201/055; H05K 1/028; H05K 1/0245

(57) ABSTRACT

A stacked insertion structure for a flexible circuit board is provided. The flexible circuit board has an insertion section that is connected through a bent connection section to a fold-back section. The fold-back section is backward folded, through the bent connection section, toward and stacked on the insertion section such that a second coupling surface of the fold-back section corresponds to and overlap a first coupling surface of the insertion section for being insertable into an insertion socket of a connector. The fold-back section and the insertion section are bonded together with an adhesive layer therebetween or a height adjustment layer is provided therebetween to adjust an overall height of the two.

### BACKGROUND OF THE INVENTION

### 1. Field of the Invention

The present invention relates to an insertion structure of a flexible circuit board, and in particular to a stacked insertion structure of a flexible circuit board.

### 2. The Related Arts

Flexible circuit boards are advantageous of being flexible, thin, and light in weight and have been widely used in various fields of electronic products. A fabrication process only requires an insertion or connection structure to provide conductive connection between two devices. It is commonplace to use a rigid circuit board as a substrate and multiple conductor pads are formed on top and bottom surfaces of the substrate. The use of the rigid substrate suffers being constrained by inflexibility of the substrate and additional measures, such as soldering, flexible flat cables, and flexible circuit boards, must be used for adaption to a device space or common practices of operation of a product. This inevitably increases the fabrication cost and wastes the device space.

The connection or insertion structures could be made with for example electronic flat cables printed on films, flexible flat cable, flexible printed circuit boards. However, due to the inherent property of flexibility, the flexible circuits do not provide a sufficient mechanical strength for insertion and thus, do not suit the requirements of the contemporary techniques.

### SUMMARY OF THE INVENTION

In view of the shortcomings of the prior art, an objective of the present invention is to provide a stacked insertion structure of a flexible circuit board, in which an insertion terminal that is insertable into an insertion socket of a connector is formed through curving, folding, and stacking the flexible circuit board.

To achieve the above objective, the present invention provides a flexible circuit board, which has an insertion section that is connected through a bent connection section to a fold-back section. The fold-back section is backward folded, through the bent connection section, toward and stacked on the insertion section such that a second coupling surface of the fold-back section corresponds to and overlap a first coupling surface of the insertion section for being insertable into an insertion socket of a connector. The fold-back section and the insertion section are bonded together with an adhesive layer therebetween or a height adjustment layer is provided therebetween to adjust an overall height of the two.

In efficacy, an insertion end of the flexible circuit board according to the present invention is formed with the insertion section stacked with the fold-back section that is backward folded and stacked thereon and is thus insertable into an insertion socket of a connector. The height adjustment layer arranged between the insertion section and the fold-back section makes it possible to suit a height requirement for an actual insertion operation.

### BRIEF DESCRIPTION OF THE DRAWINGS

The present invention will be apparent to those skilled in the art by reading the following description of preferred embodiments of the present invention, with reference to the attached drawings, in which:

FIG. 1 is a perspective view showing a flexible circuit board according to a first embodiment of the present invention in an expanded form;

FIG. 2 is a top plan view of the flexible circuit board according to the first embodiment of the present invention in the expanded form;

FIG. 3 is a perspective view showing the flexible circuit board according to the first embodiment of the present invention in a folded and stacked form;

FIG. 4 is a cross-sectional view taken along line 4-4 of FIG. 3;

FIG. 5 is perspective view showing the flexible circuit board of FIG. 3, in the folded and stacked form, being in a condition of being separate from but ready to insert into an insertion receptacle device;

FIG. 6 is a schematic view illustrating the flexible circuit board of the present invention, in the folded and stacked condition, being in the condition of being separate from but ready to insert into the insertion receptacle device;

FIG. 7 is a schematic view illustrating the flexible circuit board of the present invention, in the folded and stacked condition, being inserted into the insertion receptacle device;

FIG. 8 is a schematic top plan view illustrating a flexible circuit board according to the present invention having an extension section extending from an insertion section in a direction perpendicular thereto;

FIG. 9 is a schematic top plan view illustrating the insertion section of the flexible circuit board of FIG. 8 being inserted into an insertion receptacle device;

FIG. 10 is a schematic view illustrating the flexible circuit board of FIG. 3 having an extension section that is combined with an enclosing protection layer;

FIG. 11 is another schematic view illustrating the flexible circuit board of FIG. 3 having an extension section that is combined with an enclosing protection layer;

FIG. 12 is a cross-sectional view showing a flexible circuit board according to a second embodiment of the present invention in a folded and stacked form; and

FIG. 13 is a cross-sectional view showing a flexible circuit board according to a third embodiment of the present invention in a folded and stacked form.

### DETAILED DESCRIPTION OF THE PREFERRED EMBODIMENTS

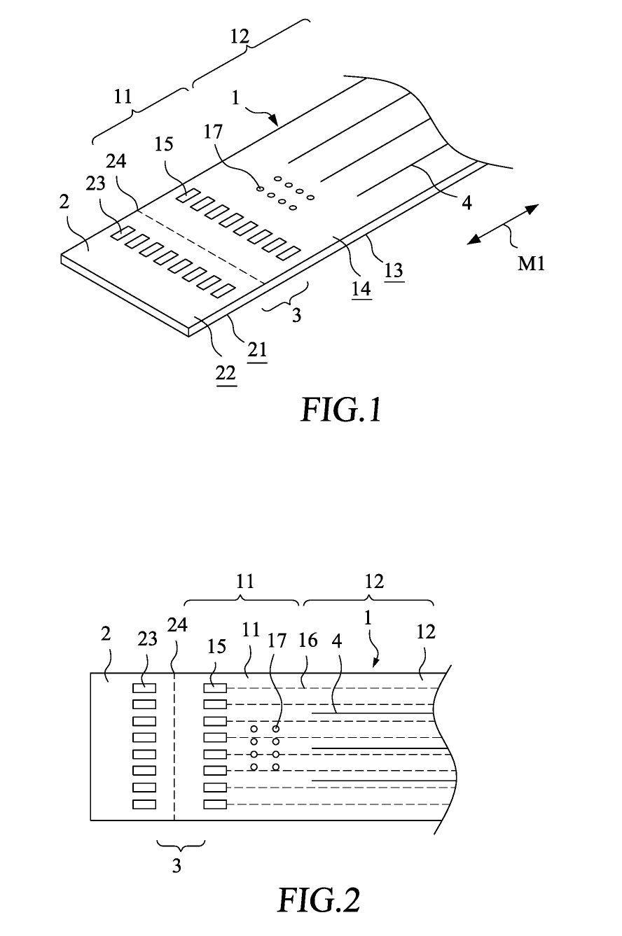

Referring to FIG. 1, which is a perspective view showing a flexible circuit board according to a first embodiment of the present invention in an expanded form. FIG. 2 is a top plan view of the flexible circuit board according to the first embodiment of the present invention in the expanded form. The flexible circuit board 1 of the instant embodiment comprises at least one insertion section 11 and an extension section 12, wherein the insertion section 11 comprises a first coupling surface 13 and a first exposed surface 14, and the extension section 12 extends from the insertion section 11, in a manner of being coplanar therewith, in an extension direction M.

In an actual application, the flexible circuit board 1 can be one of a film printing electronic flat cable, a flexible flat cable (FFC), and a flexible printed circuit board (FPC). The extension section 12 of the flexible circuit board 1 is formed, through cutting in the extension direction M, with a plurality of slit lines 4.

A plurality of first contact pads 15 are arranged, in a manner of being spaced from each other, on the first exposed surface 14 of the insertion section 11. A plurality of conductor lines 16 are arranged, in a manner of being spaced from each other, on the extension section 12 in the extension direction M. The plurality of conductor lines 16 are selectively and electrically connected to the plurality of first contact pads 15, and the plurality of conductor lines 16 comprise at least one pair of differential-mode high-frequency signal conductor lines.

The first exposed surface 14 of the insertion section 11 is further formed with at least one component solder pad 17 provided thereon for soldering with at least one electronic component (not shown). The first coupling surface 13 of the insertion section 11 may also be provided with one or more component solder pad, if desired.

The insertion section 11 is formed, on an end portion thereof that is opposite to the extension section 12, with a bent connection section 3, which is integrally connected with a fold-back section 2. The fold-back section 2 comprises a second coupling surface 21 and a second exposed surface 22. The second exposed surface 22 comprises a plurality of second contact pads 23 arranged thereon. The second contact pads 23 are selectively and electrically connected to the conductor lines arranged on the extension section 12 and the conductor lines may also comprise at least one pair of differential-mode high-frequency signal conductor lines. The second coupling surface 21 and the second exposed surface 22 of the fold-back section 2, if desired, may also be provided with one or more component solder pad 17, in a way similar to that of the first exposed surface 14 of the insertion section 11 for soldering with at least one electronic component (not shown).

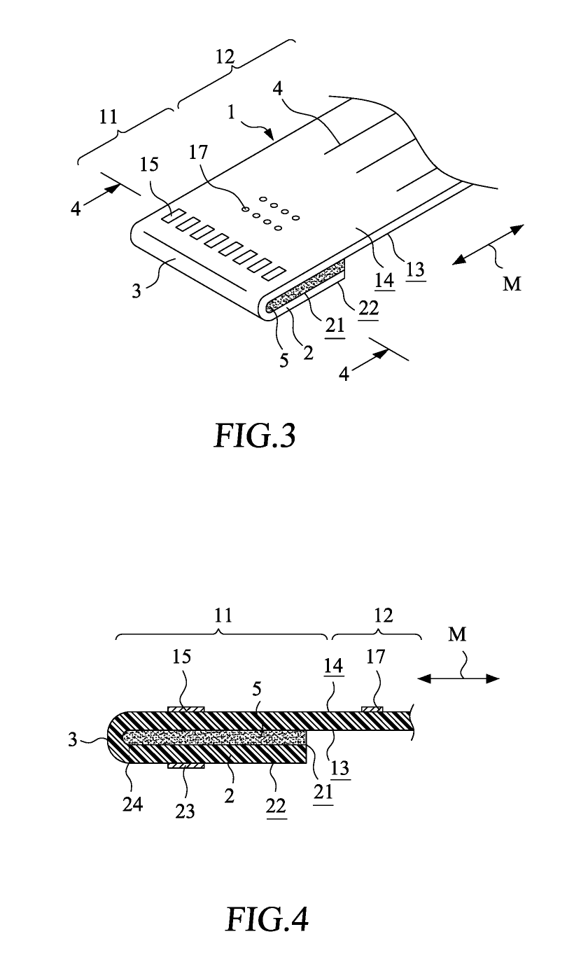

FIG. 3 is a perspective view showing the flexible circuit board according to the first embodiment of the present invention in a folded and stacked form and FIG. 4 is a cross-sectional view taken along line 4-4 of FIG. 3. As shown in the drawings, the fold-back section 2 is folded backward about a folding edge 24 of the bent connection section 3 (which is illustrated as a phantom line in FIGS. 1 and 2, but forms an edge or a corner in the folded condition of FIG. 4) in a direction of facing toward the first coupling surface 13 of the insertion section 11 to be stacked thereon so that the fold-back section 2 is stacked on and overlaps the insertion section 11. After the backward folding and stacking of the fold-back section 2, the second coupling surface 21 of the fold-back section 2 is set corresponding to and overlapping, in surface contact, the first coupling surface 13 of the insertion section 11 such that the second coupling surface 21 of the fold-back section 2 and the first coupling surface 13 of the insertion section 11 can be adhesively bonded to each other through an adhesive layer 5 coated therebetween. As shown in the drawings, a length of the coating of the adhesive layer 5 is set consistent with a length of the fold-back section 2. It is also feasible to provide the fold-back section 2 with an extended length such that a free end of the fold-back section 2 projects a length beyond an edge of the adhesive.

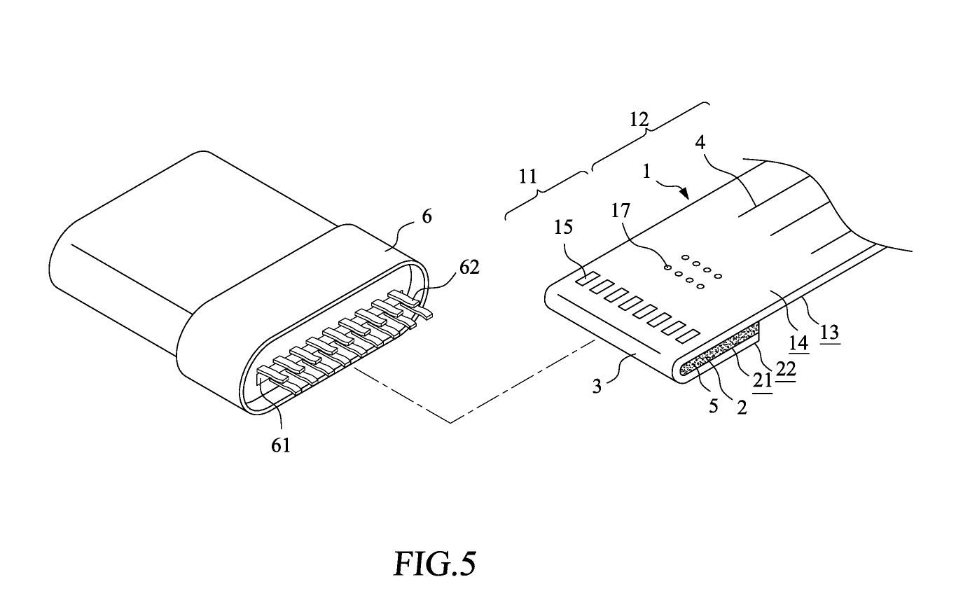

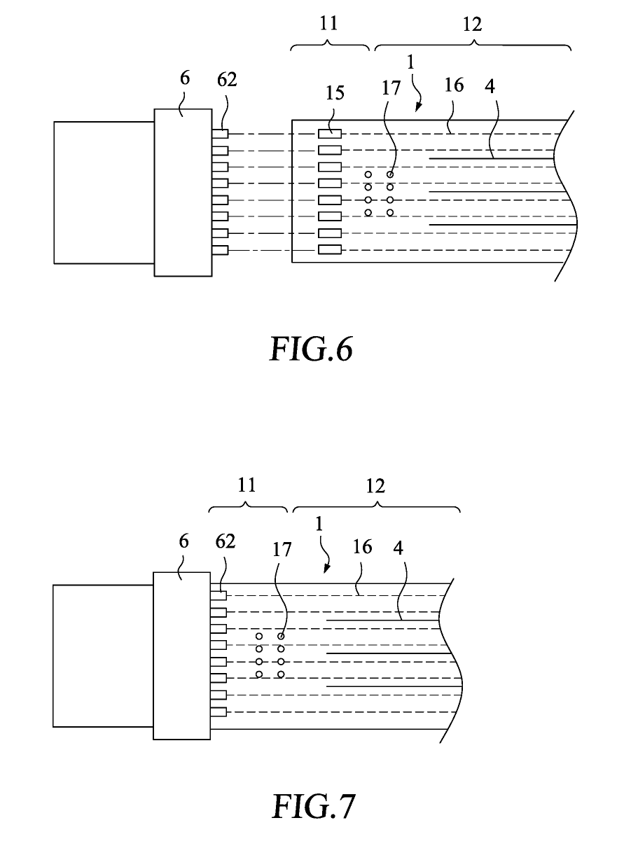

Referring to FIGS. 5-7, FIG. 5 is perspective view showing the flexible circuit board 1 of FIG. 3, in the folded and stacked form, being in a condition of being separate from but ready to insert into an insertion receptacle device 6; FIG. 6 is a schematic view illustrating the flexible circuit board 1 of the present invention, in the folded and stacked condition, being in the condition of being separate from but ready to insert into the insertion receptacle device 6; and FIG. 7 is a schematic view illustrating the flexible circuit board 1 of the present invention, in the folded and stacked condition, being inserted into the insertion receptacle device 6.

To insert, the insertion section 11 of the flexible circuit board 1 is set into an insertion socket 61 of a connector 6 such that the first contact pads 15 of the insertion section 11 and the second contact pads 23 of and the fold-back section 2 are respectively set in electrically conductive contact with conductor pins 62 arranged in the insertion receptacle device 6. If desired, the first contact pads 15 and the second contact pads 23 may be individually soldered to the conductor pins 62 of the insertion receptacle device 6 that correspond thereto. The insertion receptacle device 6 cab be a commercially available USB type C insertion receptacle device or other insertion receptacle devices.

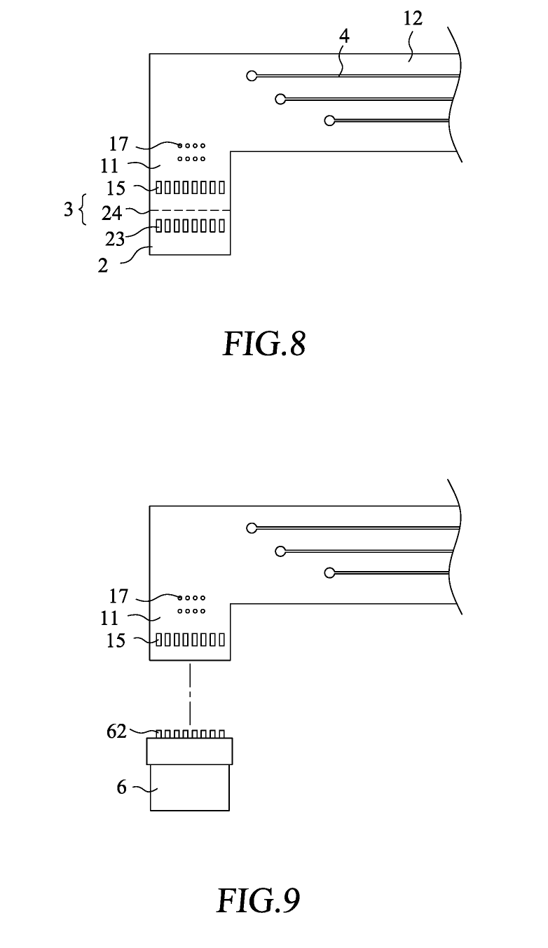

The first embodiment, as described above, is structured such that the extension section 12 is set to extend in a direction substantially parallel to the insertion section 11. In an actual application, the extension section 12 can be alternatively set to extend in a direction substantially perpendicular to the insertion section 11. FIG. 8 is a schematic top plan view illustrating the extension section 12 of the flexible circuit board 1 according to the present invention extending from the insertion section 11 in a direction perpendicular thereto. FIG. 9 is a schematic top plan view illustrating the insertion section 11 of the flexible circuit board 1 of FIG. 8 is inserted into an insertion receptacle device 6.

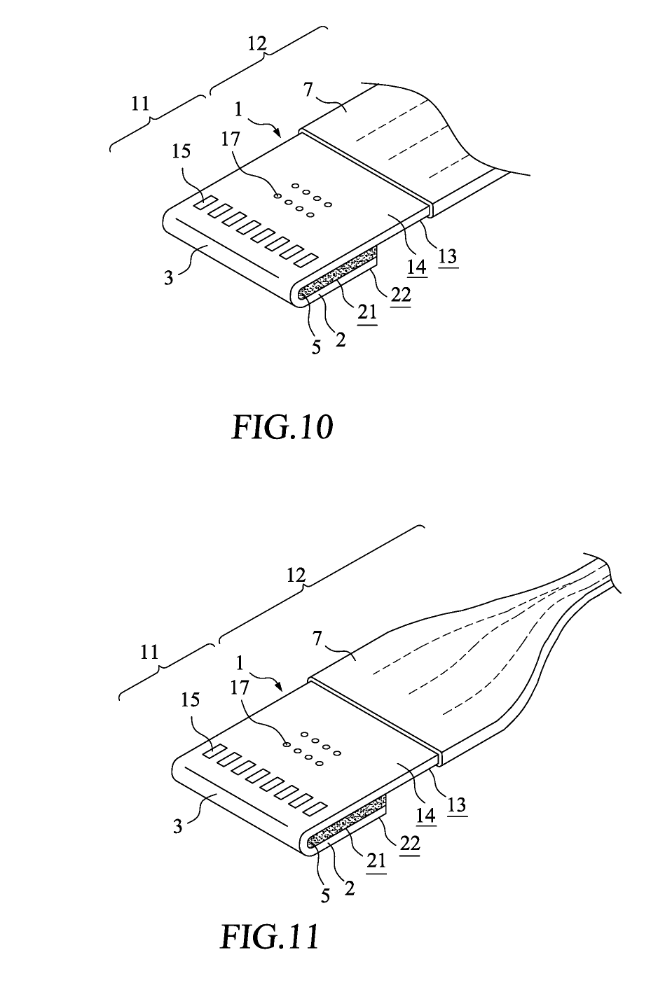

FIG. 10 is a schematic view illustrating the extension section 12 of the flexible circuit board 1 of FIG. 3 is enclosed and housed with an enclosing protection layer 7. FIG. 11 is a schematic view illustrating the extensions section 12 of the flexible circuit board 1 of FIG. 3 is first wrapped or twisted or shrunk, through the slit lines 4, in a width-reduced form and then enclosed and housed with an enclosing protection layer 7. The enclosing protection layer 7 can be made in the form of a heat-shrinkable sleeve made of a heat-shrinking material or a silicone rubber sleeve made of a silicone rubber material. The enclosing protection layer 7 can alternatively be made of one of an electrically conductive material and a magnetically conductive material.

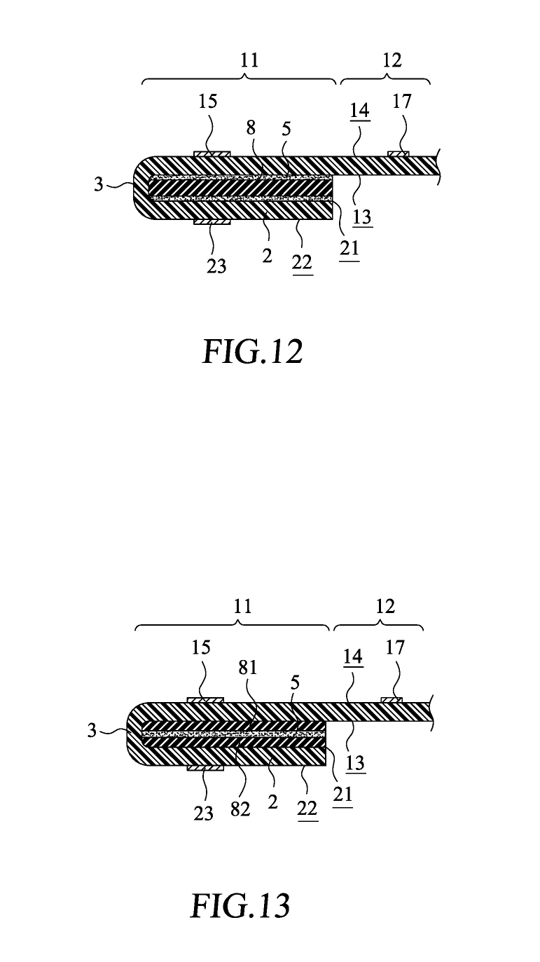

FIG. 12 is a cross-sectional view showing a flexible circuit board according to a second embodiment of the present invention in a folded and stacked form. In the instant embodiment, constituent components are generally similar to the structure of the embodiment with reference to FIG. 4 and for consistency, similar components/parts are designate with the same reference. In the instant embodiment, the fold-back section 2 of the flexible circuit board 1 further comprises a height adjustment layer 8 interposed between the second coupling surface 21 and the first coupling surface 13 of the insertion section 11 and is adhesively bonded to each of the fold-back section 2 and the insertion section 11 with an adhesive layer 5. The arrangement of the so-interposed height adjustment layer 8 makes it possible to suit to different height requirements of the insertion sockets of different insertion receptacle devices through adjustment of the overall height of the fold-back section 2 and the insertion section 11 after backward folding and stacking.

FIG. 13 is a cross-sectional view showing a flexible circuit board according to a third embodiment of the present invention in a folded and stacked form. In the instant embodiment, the first coupling surface 13 of the insertion section 11 is combined with a first height adjustment layer 81 and the second coupling surface 21 of the fold-back section 2 is combined with a second height adjustment layer 82. The first height adjustment layer 81 and the second height adjustment layer 82 are adhesively bonded together with an adhesive layer 5 applied or coated therebetween. The arrangement of the height adjustment layers 81, 82 makes it possible to suit to different height requirements of the insertion sockets of different insertion receptacle devices through adjustment of the overall height of the fold-back section 2 and the insertion section 11 after backward folding and stacking.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A flexible circuit board, comprising:
at least one insertion section having a first coupling surface and a first exposed surface;
an extension section connected to the at least one insertion section and extended from the at least one insertion section in an extension direction;
a plurality of first contact pads arranged on the first exposed surface of the at least one insertion section in a manner of being spaced from each other;
a plurality of conductor lines arranged on the extension section in the extension direction;
a fold-back section having a second coupling surface, a second exposed surface and a folding edge, the fold-back section being set such that the second coupling surface corresponds to and is stacked on the first coupling surface of the at least one insertion section; and
a bent connection section integrally connected between the at least one insertion section and the folding edge of the fold-back section;
wherein the fold-back section is folded backward, through the bent connection section, such that the second coupling surface of the fold-back section faces toward and overlaps the first coupling surface of the at least one insertion section to have the fold-back section stacked on the at least one insertion section of the flexible circuit board.

2. The flexible circuit board according to claim 1, wherein the second coupling surface of the fold-back section and the first coupling surface of the at least one insertion section are bonded together with an adhesive layer therebetween.

3. The flexible circuit board according to claim 1, wherein the fold-back section comprises a height adjustment layer interposed between the second coupling surface thereof and the first coupling surface of the at least one insertion section.

4. The flexible circuit board according to claim 1, wherein the first coupling surface of the at least one insertion section is combined with a first height adjustment layer and the second coupling surface of the fold-back section is combined with a second height adjustment layer, the first height adjustment layer and the second height adjustment layer being bonded together with an adhesive layer therebetween.

5. The flexible circuit board according to claim 1, wherein the fold-back section that is backward folded and stacked on the at least one insertion section of the flexible circuit board is adapted to insert into an insertion socket of a connector, such that the plurality of first contact pads are respectively set in electrically conductive contact with a plurality of conductor pins of the insertion receptacle device.

6. The flexible circuit board according to claim 5, wherein the plurality of first contact pads are respectively soldered to the plurality of conductor pins of the insertion receptacle device.

7. The flexible circuit board according to claim 1, wherein the plurality of conductor lines comprise at least one pair of differential-mode high-frequency signal conductor lines.

8. The flexible circuit board according to claim 1, wherein the fold-back section comprises a plurality of second contact pads arranged on the second exposed surface.

9. The flexible circuit board according to claim 8, wherein the plurality of second contact pads are soldered to a plurality of conductor pins of an insertion receptacle device.

10. The flexible circuit board according to claim 1, wherein one of the first exposed surface, the first coupling surface, the second exposed surface, and the second coupling surface comprises at least one component solder pad arranged thereon for soldering with at least one electronic component.

11. The flexible circuit board according to claim 1, wherein the flexible circuit board comprises one of a film printing electronic flat cable, a flexible flat cable (FFC), and a flexible printed circuit board (FPC).

12. The flexible circuit board according to claim 1, wherein the extension section of the flexible circuit board is formed with a plurality of slit lines through cutting in the extension direction.

13. The flexible circuit board according to claim 1, wherein the extension section of the flexible circuit board is enclosed and housed with an enclosing protection layer.

14. The flexible circuit board according to claim 1, wherein the enclosing protection layer comprise one of a heat-shrinkable sleeve, a silicone rubber sleeve, an electrically conductive layer, and a magnetically conductive layer.
